(19) United States
(12) Patent Application Publication
(10) Pub. No.: US 2025/0364293 A1
(43) Pub. Date: Nov. 27, 2025

(54) Battery String Typesetting and Welding All-In-One Machine

(71) Applicant: WUXI BORYUAN INTELLIGENT EQUIPMENT CO., LTD., Wuxi (CN)

(72) Inventors: Jianhang Yao, Wuxi (CN); Kai Wei, Wuxi (CN); Kepeng Wu, Wuxi (CN); Shuisheng Li, Wuxi (CN)

(21) Appl. No.: 19/294,154

(22) Filed: Aug. 7, 2025

Related U.S. Application Data
(63) Continuation of application No. PCT/CN2025/071369, filed on Jan. 8, 2025.

(30) Foreign Application Priority Data
Feb. 6, 2024 (CN) 2024101671261

(51) Int. Cl. H01L 21/677; B23K 13/00; B23K 37/02; B23K 37/04; B23K 101/36; H01L 21/683; H10F 19/90

(52) U.S. Cl. CPC H01L 21/67754; B23K 37/0229; B23K 37/0426; H01L 21/6838; B23K 13/00; B23K 2101/36; H10F 19/902

(57) ABSTRACT

The invention belongs to the technical field of photovoltaic preparation equipment, in particular to a battery string typesetting and welding all-in-one machine, which comprises a frame, wherein a cross beam is arranged on the frame; A battery string transmission device arranged on the frame below one end of the cross beam; A typesetting deviation correcting device arranged at one end of the beam; A vacuum receiving device arranged in the middle of the rack; A battery string welding device arranged at the other end of the beam; The control device arranged on the frame comprises a control box arranged on the frame, and a controller and a touch display screen are arranged on the control box. By integrating the function of the typesetting machine and the welding, and optimizing the transmission structure, the invention simplifies equipment design, improves production processes, enhances efficiency, reduces costs, and maximizes economic benefits.

### TECHNICAL FIELD

The invention belongs to the technical field of photovoltaic preparation equipment, in particular to a battery string typesetting and welding all-in-one machine.

### BACKGROUND ART

Solar energy is a kind of renewable and clean energy, and the use of solar energy to generate electricity has been increasingly valued and favored by people. Solar cell module is a power generation device that converts light energy into electric energy. As the main raw material of solar cell module, the processing of solar cell is also a very important link.

At present, the typesetting machine puts the battery strings from the series welding machine on the glass, then flows into the lap welding machine, and then the battery strings and the bus bars are welded together by the lap welding machine.

In the current production process, it is necessary to optimize the production equipment and the production process of solar cells in order to reduce costs and increase efficiency and improve the competitiveness of solar cell modules. Therefore, engineers in this field have developed a device that combines the placement function of typesetting machine with the welding function of lap welder to form a brand-new typesetting and welding machine.

### SUMMARY

In order to solve the problems in related technologies, the invention provides a battery string typesetting and welding integrated machine, which combines the placement function of the typesetting machine with the welding function of the lap welder, aiming at optimizing the equipment structure, optimizing the production process, improving the production efficiency, reducing the equipment cost and solving the problems raised in the background technology.

The technical scheme of this patent is as follows:

The battery string typesetting and welding all-in-one machine comprises a frame, wherein a cross beam is arranged on the frame; The battery string transmission device arranged on the frame below one end of the cross beam comprises a support frame arranged on the frame, wherein a plurality of groups of receiving mechanisms are arranged on the support frame, and the battery string transmission mechanism is arranged on the support frame; The typesetting rectification device arranged at one end of the beam comprises a rotary lifting typesetting mechanism assembled on the beam, and the frame is provided with a visual mechanism corresponding to the rotary lifting typesetting mechanism; The vacuum receiving device arranged in the middle of the frame comprises a vacuum receiving frame arranged on the frame and located below the cross beam, and a vacuum receiving plate component on the vacuum receiving frame; A battery string welding device arranged at the other end of the beam, wherein the battery string welding device comprises a sheet suction mechanism and a string welding mechanism arranged at both sides of the beam; The film suction mechanism comprises a movable film suction base assembled on the cross beam, and a film suction component is installed on the movable film suction base; The series welding mechanism comprises a welding base, and an electromagnetic welding component is installed on the welding base; The frame is provided with a welding workbench corresponding to the electromagnetic welding assembly; The control device arranged on the frame comprises a control box arranged on the frame, and a controller and a touch display screen are arranged on the control box; The controller is connected with a first receiving mechanism, a battery string conveying mechanism, a rotary lifting typesetting mechanism, a vision mechanism, a vacuum receiving plate assembly, a sheet suction mechanism and a string welding mechanism through connecting wires.

Further technical scheme, the material receiving mechanism comprises a material receiving seat slidably mounted on the support frame, and both sides of the material receiving seat are slidably mounted on the support frame; The support frame is connected with a driving motor, the driving motor is connected with a gear box in a transmission way, and the gear box is connected with a screw rod placed at an angle of 90 degrees with the driving motor in a transmission way; The lower part of the material receiving seat is provided with a threaded hole, and the screw rod and the threaded hole are in transmission connection through threaded connection.

In the further technical scheme, a chute is arranged on the upper end face of the support frame, and the bottom of the chute is provided with Positioning groove; The positioning groove is clamped with a positioning track; The lower part of the receiving seat is provided with a clamping seat slidably installed in the chute, and the lower end of the clamping seat is slidably installed on the positioning rail.

Further technical scheme, the battery string conveying mechanism comprises a conveying frame installed on the supporting frame, one end of the conveying frame is provided with a contact seat, and the contact seat is provided with a conveying motor and an infrared sensor facing the inner side of the frame; A plurality of roller shafts are mounted on the conveying frame, and a transmission shaft is mounted on the contact seat, and the transmission shaft is in transmission connection with a conveying motor; A conveyor belt is wound around all the roller shafts and transmission shafts.

In a further technical scheme, the rotary lifting typesetting mechanism comprises a beam track installed on a beam, a typesetting base is slidably installed on the beam track, and a typesetting linear motor in transmission connection with the typesetting base is installed on the beam;

A typesetting installation frame is installed on one side of the typesetting base, a typesetting installation vertical plate is installed on the typesetting installation vertical plate, a typesetting installation horizontal plate is installed on the typesetting installation horizontal plate, and a vertical typesetting cylinder is installed on the typesetting installation horizontal plate, and the typesetting cylinder is in transmission connection with a typesetting rotary seat; A typesetting rotary motor is mounted on the typesetting rotary seat, and the typesetting rotary motor is drivingly connected with a rotary shaft; the lower end of the rotary shaft is connected with a typesetting rack; the lower end of the typesetting rack is provided with a plurality of typesetting sucker groups; and the typesetting mounting rack is equipped with a vacuum generator, which is communicated with the typesetting sucker groups through pipelines.

In a further technical scheme, the typesetting sucker group comprises a typesetting sucker bracket installed at the lower part of the typesetting rack, and a plurality of typesetting suckers are installed on the typesetting sucker bracket.

In a further technical scheme, the vision mechanism comprises a vision bracket installed on a cross beam, and the top of the vision bracket is provided with an additional vision bracket; The side surface of the vision bracket is provided with a vision chute, a plurality of vision mounting brackets are slidably connected in the vision chute, and a rectification camera is installed in each vision mounting bracket; A plurality of vision mounting brackets are installed on the additional vision bracket, and a rectification camera is installed in each vision mounting bracket.

In a further technical scheme, the vacuum receiving plate assembly comprises a vacuum receiving plate installed on the vacuum receiving frame, wherein a plurality of receiving grids are uniformly arranged on the vacuum receiving plate, and a plurality of vacuum holes are arranged in each receiving grid, and each vacuum hole is communicated with a vacuum channel penetrating through the vacuum receiving plate; and a vacuum generator is arranged on the frame, and the vacuum generator is communicated with each vacuum channel through a pipeline.

In a further technical scheme, the movable suction base comprises a suction linear motor installed at one side of the cross beam and a suction guide rail arranged at one side of the cross beam, and a suction bracket in transmission connection with the suction linear motor is slidably connected to the suction guide rail; Two suction moving brackets are arranged on both sides of the lower part of the suction bracket, each suction moving bracket is provided with a suction linear motor and a suction sliding seat in transmission connection with the suction linear motor, and the suction cup sliding seat is slidably installed on the suction moving bracket; A film suction workbench is arranged between the two film suction sliding seats; A vertical suction bracket is installed on the suction workbench, a suction vertical cylinder is installed at the top of the vertical suction bracket, and the suction vertical cylinder is connected with a suction lifting seat in a transmission way; The lower part of the suction lifting seat is provided with a plurality of suction cross bars, the lower part of each suction cross bar is provided with a plurality of suction cup brackets, and a plurality of suction cups are mounted on the suction cup brackets; The suction table is provided with a suction vacuum generator, and the suction vacuum generator is communicated with each suction cup through a pipeline.

Further technical scheme, the electromagnetic welding assembly comprises a welding linear motor installed on the welding base, and the welding linear motor is connected with a welding lifting workbench in a transmission way; The welding lifting workbench is provided with a junction box and a plurality of electromagnetic welding driving plates, and the lower part of the welding lifting workbench is provided with a plurality of electromagnetic welding heads, and the junction box is communicated with an external controller and electrically connected with all the electromagnetic welding driving plates; The electromagnetic welding drive The board is electrically connected with the electromagnetic welding head one by one.

By adopting the technical scheme, compared with the prior art, the invention has the following beneficial effects:

According to the invention, the functions of the typesetter and the welder are combined, and the transmission structure is optimized, so that the equipment structure is optimized, and the production process is improved, so that the purposes of improving the production efficiency and reducing the equipment cost are achieved, and the maximum economic benefit is achieved.

It should be understood that both the above general description and the following detailed description are exemplary only and are not restrictive of the invention.

### BRIEF DESCRIPTION OF DRAWINGS

he accompanying drawings, which are incorporated in and constitute a part of this specification, illustrate embodiments consistent with the invention and together with the description, serve to explain the principles of the invention.

FIG. 1 is a schematic diagram of the overall structure of the present invention.

FIG. 2 is a schematic working diagram of the battery string transmission device of the present invention.

FIG. 3 is a schematic diagram of the rotary lifting typesetting mechanism of the present invention.

FIG. 4 is a schematic diagram of the vision mechanism of the present invention.

FIG. 5 is a schematic working diagram of the vacuum receiving device of the present invention.

FIG. 6 is a schematic working diagram of the film suction mechanism of the present invention.

FIG. 7 is a schematic working diagram of the series welding mechanism of the present invention.

In the figure, 1. Battery string transmission device; 2. Rotary lifting typesetting mechanism; 3. Visual organization; 4. Vacuum material receiving device; 5. Film suction mechanism; 6. Rack; 7. Cross beam; 8. Series welding mechanism; 9. The first driving motor; 10. First coupling; 11. The first gear box; 12. The second gear box; 13. Second coupling; 14. The second driving motor; 15. The first receiving seat; 16. Conveyor belt; 17. Infrared sensor; 18. Contact seat; 19. Roller shaft; 20. Transfer motor; 21. The second receiving seat; 22. Support frame; 23. Chute; 24, positioning track; 25. Positioning groove; 26. Contact switch; 27, typesetting base; 28, typesetting vertical plate installation; 29, typesetting installation transverse plate; 30, typesetting cylinder; 31, beam track; 32, typesetting sucker bracket; 33. Vacuum generator; 34, typesetting installation frame; 35, typesetting rotary seat; 36, typesetting frame; 37, typesetting sucker; 38. Rectify the camera; 39. Visual mounting bracket; 40, visual support; 41. Additional visual support; 42. L-shaped connecting plate; 43, vacuum receiving frame; 44. Vacuum hole; 45. Vacuum channel; 46. Vacuum receiving plate; 47, welding base; 48. Junction box; 49, electromagnetic welding drive plate; 50, welding mold; 51, welding head mounting frame; 52. Welding lifting workbench; 53, electromagnetic welding head; 54, suction linear motor; 55. Film suction workbench; 56. Movable support for suction film; 57, suction vertical cylinder; 58, mobile suction base; 59. Welding workbench; 60, suction bar; 61. Suction disc; 62. Vertical suction bracket.

### DETAILED DESCRIPTION

Reference will now be made in detail to exemplary embodiments, examples of which are illustrated in the accompanying drawings. When the following description refers to the drawings, unless otherwise indicated, the same numbers in different drawings indicate the same or similar elements. The embodiments described in the following exemplary embodiments do not represent all embodiments consistent with the present invention. Rather, they are merely examples of devices and methods consistent with some aspects of the invention as detailed in the appended claims.

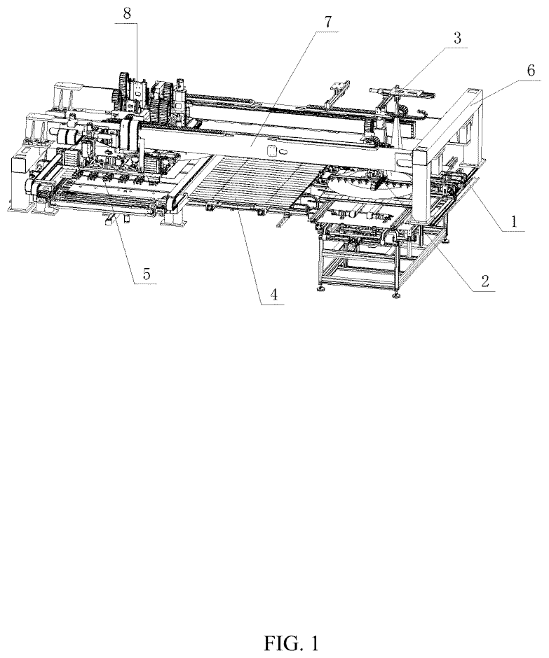

As shown in FIG. 1, this embodiment discloses a battery string typesetting and welding all-in-one machine, which comprises a frame 6, and a cross beam 7 is arranged on the frame 6. A vision mechanism 3, a rotary lifting typesetting mechanism 2, a film suction mechanism 5 and a series welding mechanism 8 are sequentially assembled on the cross beam 7.

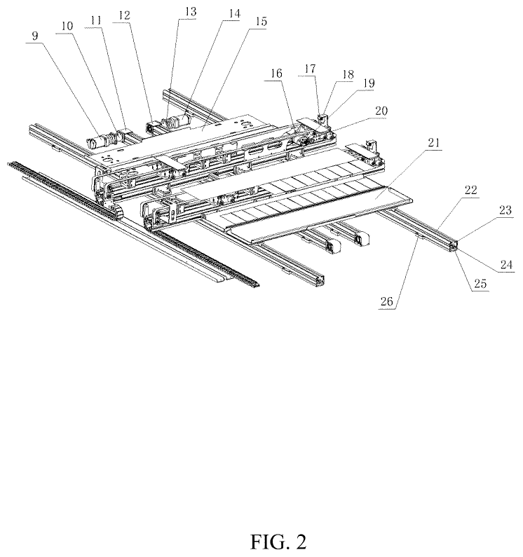

As shown in FIG. 2, the battery string transmission device 1 arranged on the frame below one end of the cross beam includes the battery string transmission device 1 arranged on the frame 6. A support frame 22, on which a plurality of groups of receiving mechanisms are installed, and on which a battery string conveying mechanism is installed. The two receiving mechanisms are a group, including a first receiving mechanism and a second receiving mechanism. The first receiving mechanism includes a first receiving seat 15 slidably mounted on the support frame 22, and the second receiving mechanism includes a second receiving seat 21 slidably mounted on the support frame 22. Both sides of the first receiving seat 15 and the second receiving seat 21 are slidably mounted on the support frame 22.

Two first driving motors 9 and second driving motors 14 are connected to the support frame 22. The first driving motor 9 is drivingly connected with a first gear box 11, and the first gear box 11 is drivingly connected with a screw rod placed at an angle of 90 degrees with the first driving motor 9. The lower part of the first receiving seat 15 is provided with a threaded hole, and the screw rod and the threaded hole are in transmission connection through threaded connection. The second driving motor 14 is drivingly connected with a second gear box 12, and the second gear box 12 is drivingly connected with a screw rod placed at an angle of 90 degrees with the second driving motor 14. The lower part of the second receiving seat 21 is provided with a threaded hole, and the screw rod and the threaded hole are in transmission connection through threaded connection. In order to control the rotation speed and smooth transmission, a first coupling 10 is arranged between the first driving motor 9 and the first gear box 11, and a second coupling 13 is arranged between the second driving motor 14 and the second gear box 12.

The upper end face of the support frame 22 is provided with a chute 23, and the bottom of the chute 23 is provided with a positioning groove 25, and the positioning rail 24 is clamped on the positioning groove 25. The lower parts of the first receiving seat 15 and the second receiving seat 21 are provided with clamping seats slidably installed in the chute 23, and the lower ends of the clamping seats are slidably installed on the positioning rail.

The battery string conveying mechanism includes a conveying frame mounted on a support frame 22, and a contact seat 18 is mounted at one end of the conveying frame, and a conveying motor 20 and an infrared sensor 17 facing the inside of the frame are mounted on the contact seat 18. A plurality of roller shafts 19 are mounted on the conveying frame, and a transmission shaft is mounted on the contact seat 18, and the transmission shaft is drivingly connected with the conveying motor. A conveyor belt 16 is wound around all the roller shafts and transmission shafts. The battery string is transported to the receiving seat through an external process, and then transported by a conveyor belt for further processing.

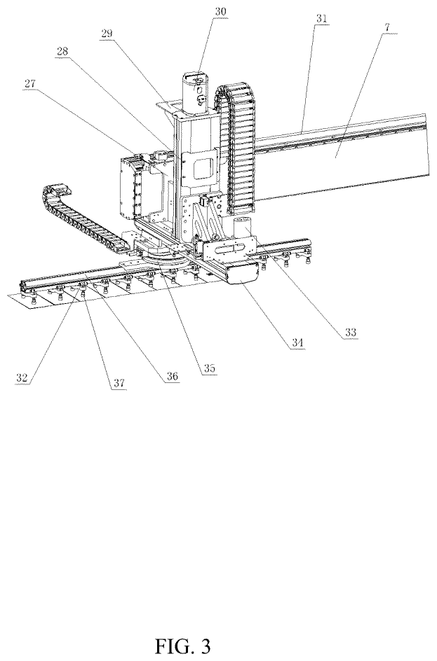

The typesetting rectification device arranged at one end of the cross beam comprises a rotary lifting typesetting mechanism assembled on the cross beam 7, and the frame 6 is provided with a vision mechanism 3 corresponding to the rotary lifting typesetting mechanism 2. As shown in FIG. 3, the rotary lifting typesetting mechanism includes a beam rail 31 installed on the beam 7, a typesetting base 27 is slidably installed on the beam rail 31, and a typesetting linear motor is installed on the beam 7 in a transmission connection with the typesetting base. The typesetting linear motor is drivingly connected with the typesetting base 27 to drive the typesetting base 27 to move. A typesetting mounting frame 34 is installed on one side of the typesetting base 27, and a typesetting vertical plate 28 is installed on the typesetting mounting frame 34. A typesetting horizontal plate 29 is installed on the upper part of the typesetting vertical plate 28, and a vertical typesetting cylinder 30 is installed on the typesetting horizontal plate 29, and the typesetting cylinder is connected with a typesetting rotary seat 35 in a transmission way. A typesetting rotary motor is mounted on the typesetting rotary seat 35, and the typesetting rotary motor is connected with a rotary shaft in a transmission way. The lower end of the rotary shaft is connected with a typesetting rack 36, and the lower end of the typesetting rack is provided with a plurality of typesetting sucker groups, and the typesetting mounting rack is equipped with a vacuum generator 33, which is communicated with the typesetting sucker groups through a pipeline. The typesetting sucker group comprises a typesetting sucker bracket 32 installed at the lower part of the typesetting frame, and a plurality of typesetting suckers 37 are installed on the typesetting sucker bracket 32.

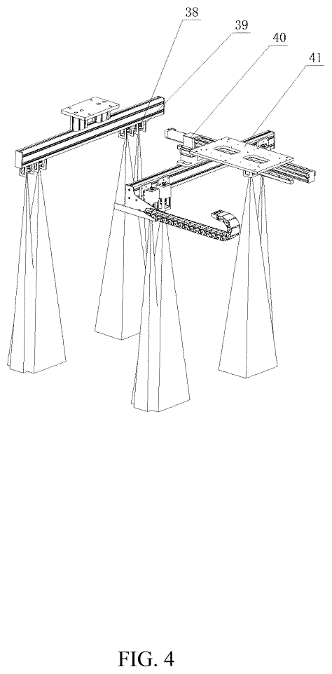

There may be one or two visual institutions, which are determined according to the actual situation. As shown in FIG. 4, the vision mechanism includes a vision bracket 40 installed on the cross beam 7, and an additional vision bracket 41 is arranged at the top of the vision bracket 40. The side surface of the vision bracket 40 is provided with a vision chute, and a plurality of vision mounting brackets 39 are slidably connected in the vision chute, and each vision mounting bracket 39 is internally provided with a rectification camera 38. A plurality of vision mounting brackets are installed on the additional vision bracket, and a rectification camera is installed in each vision mounting bracket.

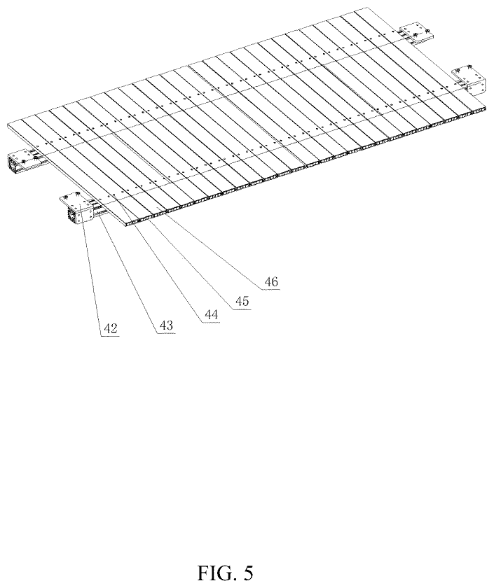

As shown in FIG. 5, the vacuum receiving device located in the middle of the machine frame 6 includes a vacuum receiving frame 43 installed on the machine frame 6 and below the cross beam 7, and a vacuum receiving plate assembly on the vacuum receiving frame. In this embodiment, both ends of the vacuum receiving frame 43 are respectively mounted on the frame through L-shaped connecting plates 42 and bolts. In this embodiment, the vacuum receiving plate assembly includes a vacuum receiving plate 46 installed on the vacuum receiving frame 43, and a plurality of receiving grids are uniformly arranged on the vacuum receiving plate 46, and each receiving grid.

A plurality of vacuum holes 44 are arranged in the grid, and each vacuum hole 44 is communicated with a vacuum channel 45 penetrating through a vacuum receiving plate 46. A vacuum generator (not shown) is arranged on the frame, and the vacuum generator communicates with each vacuum channel 45 through a pipeline.

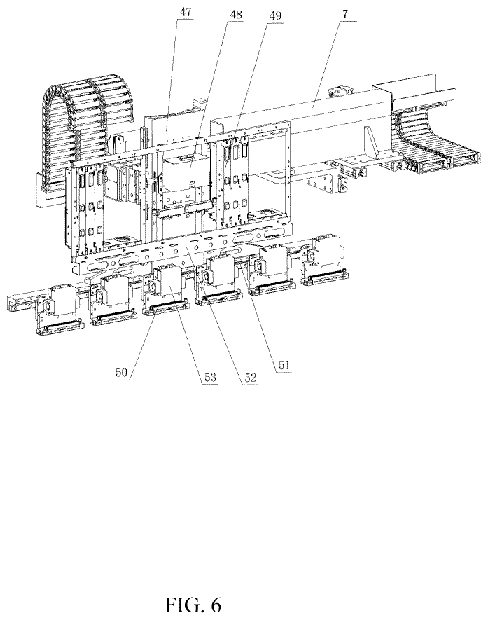

The battery string welding device arranged at the other end of the cross beam 7 comprises a sheet suction mechanism and a string welding mechanism installed at both sides of the cross beam 7. As shown in FIG. 6, the film suction mechanism includes a movable film suction base 58 mounted on the cross beam 7, and a film suction assembly is mounted on the movable film suction base 58. The movable film suction base comprises a film suction linear motor installed on one side of the cross beam 7 and a film suction guide rail installed on one side of the cross beam 7, and a film suction bracket in transmission connection with the film suction linear motor is slidably connected on the film suction guide rail. Two suction moving brackets 56 are arranged on both sides of the lower part of the suction bracket, and each suction moving bracket 56 is provided with a suction linear motor 54 and a suction sliding seat in transmission connection with the suction linear motor 54, and the suction cup sliding seat is slidably installed on the suction moving bracket 56. A film suction table 55 is installed between the two film suction sliding seats. A vertical film suction bracket 62 is mounted on the film suction table 55, and a film suction vertical cylinder 57 is mounted on the top of the vertical film suction bracket 62, and the film suction vertical cylinder 57 is connected with a film suction lifting seat in a transmission way. The lower part of the suction lifting seat is provided with a plurality of suction cross bars 60, and the lower part of each suction cross bar 60 is provided with a plurality of suction cup brackets, and a plurality of suction cups 61 are mounted on the suction cup brackets. A film suction vacuum generator (not shown) is installed on the film suction table, and the film suction vacuum generator communicates with each film suction cup 61 through a pipeline.

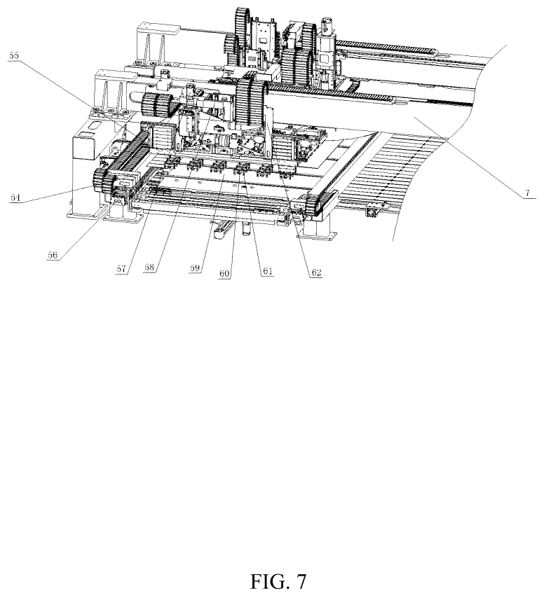

As shown in FIG. 7, the series welding mechanism includes a welding base 47 on which an electromagnetic welding assembly is mounted. The frame is provided with a welding workbench 59 corresponding to the electromagnetic welding assembly. The electromagnetic welding assembly comprises a welding linear motor installed on the welding base 47, and the welding linear motor is connected with a welding lifting table 52 in a transmission way. A junction box 48 and a plurality of electromagnetic welding driving plates 49 are installed on the welding lifting table 52, and a plurality of electromagnetic welding heads 53 are arranged at the lower part of the welding lifting table. The junction box is connected with an external controller and electrically connected with all the electromagnetic welding driving plates 49. The electromagnetic welding driving plate is electrically connected with the electromagnetic welding head one by one. In order to facilitate the welding of battery strings and bus bars, a welding die 50 for welding operation is installed at the lower part of the electromagnetic welding head 53.

In the optimized design, the lower part of the welding lifting table 52 is provided with a welding head mounting frame 51. The welding die 50 is installed at the lower part of the welding head mounting frame 51, and the electromagnetic welding head 53 is installed above it. The welding die 50 corresponds to the electromagnetic welding head 53 one by one.

The control device arranged on the rack comprises a control box arranged on the rack, and a controller and a touch display screen are arranged on the control box; The controller is connected with a first receiving mechanism, a battery string conveying mechanism, a rotary lifting typesetting mechanism, a vision mechanism, a vacuum receiving plate assembly, a sheet suction mechanism and a string welding mechanism through connecting wires. For the convenience of control, a contact switch 26 is installed on the support frame. When the first receiving seat or the second receiving seat touches the contact switch, it means that the stroke has reached the outermost side, and the controller controls the motor to work, moving inward for a short distance or feeding in the box.

In this embodiment, the controller is an industrial computer or PLC. Industrial computer or PLC can embed self-developed programs to carry out fully automatic work.

During operation, the battery string enters the first receiving seat and the second receiving seat from the external process, and at this time, the first driving motor and the second driving motor control the two receiving seats to move inward. The battery string is taken from the receiving seat to the conveyor belt under the action of the third-party mechanical arm. The conveyor belt places the battery string in the receiving grid on the vacuum receiving plate. In the process of transmission, the typesetting and rectifying device grabs the battery string with incorrect position detected by the vision system and corrects the deviation. Finally, it is grabbed by the film suction mechanism, and the battery string welding mechanism welds the battery string.

The suction cup sucks the battery string under the action of the action unit, places the bus bars from other processes, and then realizes welding under the work of the electromagnetic welding head.

The battery string transmission device in the present invention is used to send the battery string from the serial welding machine to the designated position, and the typesetting and correcting device is used to correct the deviation when the battery string is picked up. The basis for correcting the deviation is that the camera takes pictures of the battery string, and the controller extracts the position information and feeds it back to the rotary lifting and typesetting mechanism. The vacuum receiving device puts the corrected battery string in vacuum connection.

On the material rack, the rear suction mechanism and series welding mechanism weld the battery string with the bus bars coming from other processes.

According to the invention, the functions of the typesetting machine and the welding machine are combined, and the transmission structure is optimized, so that the equipment structure is optimized, and the production process is improved, so that the purposes of improving the production efficiency and reducing the equipment cost are achieved, and the maximum economic benefit is achieved.

Those skilled in the art will easily think of other embodiments of the invention after considering the specification and practicing the invention invented here. This application is intended to cover any variation, use or adaptation of the present invention, which follows the general principles of the present invention and includes common sense or common technical means in this technical field that the present invention has not invented. The specification and examples are to be regarded as exemplary only, with the true scope and spirit of the invention being indicated by the appended claims.

It should be understood that the present invention is not limited to the precise structure described above and shown in the drawings, and various modifications and changes can be made without departing from its scope. The scope of the present invention is limited only by the appended claims.

1. An all-in-one machine for typesetting and welding battery strings, which is characterizedby comprising: a frame, wherein a cross beam isarranged on the frame;
The battery string transmission device arranged on the frame below one end of the cross beam comprises a support frame arranged on the frame, wherein a plurality of groups of receiving mechanisms are arranged on the support frame, and the battery string transmission mechanism is arranged on the support frame;
the typesetting rectification device arranged at one end of the beam comprises a rotary lifting typesetting mechanism assembled on the beam, and the frame is provided with a visual mechanism corresponding to the rotary lifting typesetting mechanism;
the vacuum receiving device arranged in the middle of the frame comprises a vacuum receiving frame arranged on the frame and located below the cross beam, and a vacuum receiving plate component on the vacuum receiving frame;
a battery string welding device arranged at the other end of the beam, wherein the battery string welding device comprises a sheet suction mechanism and a string welding mechanism arranged at both sides of the beam; The film suction mechanism comprises a movable film suction base assembled on the cross beam, and a film suction component is installed on the movable film suction base; The series welding mechanism comprises a welding base, and an electromagnetic welding component is installed on the welding base; The frame is provided with a welding workbench corresponding to the electromagnetic welding assembly;
the control device arranged on the frame comprises a control box arranged on the frame, and a controller and a touch display screen are arranged on the control box; The controller is connected with a first receiving mechanism, a battery string conveying mechanism, a rotary lifting typesetting mechanism, a vision mechanism, a vacuum receiving plate assembly, a sheet suction mechanism and a string welding mechanism through connecting wires.

2. The all-in-one machine for typesetting and welding battery strings according to claim 1, characterized in that the receiving mechanism comprises a receiving seat slidably mounted on the support frame, and both sides of the receiving seat are slidably mounted on the support frame; The support frame is connected with a driving motor, the driving motor is connected with a gear box in a transmission way, and the gear box is connected with a screw rod placed at an angle of 90 degrees with the driving motor in a transmission way; The lower part of the material receiving seat is provided with a threaded hole, and the screw rod and the threaded hole are in transmission connection through threaded connection.

3. The all-in-one machine for typesetting and welding battery strings according to claim 2, characterized in that the upper end face of the support frame is provided with a chute, and the bottom of the chute is provided with a positioning groove; The positioning groove is clamped with a positioning track; The lower part of the receiving seat is provided with a clamping seat slidably installed in the chute, and the lower end of the clamping seat is slidably installed on the positioning rail.

4. The all-in-one machine for typesetting and welding battery strings according to claim 3, characterized in that the battery string conveying mechanism comprises a conveying frame installed on the supporting frame, and one end of the conveying frame is provided with a contact seat, and the contact seat is provided with a conveying motor and an infrared sensor facing the inner side of the frame; A plurality of roller shafts are mounted on the conveying frame, and a transmission shaft is mounted on the contact seat, and the transmission shaft is in transmission connection with a conveying motor; A conveyor belt is wound around all the roller shafts and transmission shafts.

5. The all-in-one machine for typesetting and welding battery strings according to claim 4, characterized in that the rotary lifting typesetting mechanism comprises a beam track installed on a beam, a typesetting base is slidably installed on the beam track, and a typesetting linear motor is installed on the beam in a transmission connection with the typesetting base.
one side of the typesetting base is provided with a typesetting mounting frame, a typesetting mounting vertical plate is mounted on the typesetting mounting frame, a typesetting mounting transverse plate is mounted on the upper part of the typesetting mounting vertical plate, a vertical typesetting cylinder is mounted on the typesetting mounting transverse plate, and the typesetting cylinder is connected with a typesetting rotary seat in a transmission way; A typesetting rotary motor is mounted on the typesetting rotary seat, and the typesetting rotary motor is drivingly connected with a rotary shaft; the lower end of the rotary shaft is connected with a typesetting rack; the lower end of the typesetting rack is provided with a plurality of typesetting sucker groups; and the typesetting mounting rack is equipped with a vacuum generator, which is communicated with the typesetting sucker groups through pipelines.

6. The all-in-one machine for typesetting and welding battery strings according to claim 5, characterized in that the typesetting sucker group comprises a bracket installed at the lower part of the typesetting rack and provided with typesetting suckers, and a plurality of typesetting suckers are installed on the typesetting sucker bracket.

7. The all-in-one machine for typesetting and welding battery strings according to claim 6, which is characterized in that the vision mechanism comprises a vision bracket installed on a beam, and the top of the vision bracket is provided with an additional vision bracket; A visual chute is arranged on the side of the visual bracket, and a plurality of visual mounting brackets are connected in the visual chute in a sliding way, and a deviation correction camera is installed in each of the visual mounting brackets; A plurality of vision mounting brackets are installed on the additional vision mounting bracket, and a deviation correction camera is installed in each of the vision mounting brackets.

8. The all-in-one machine for typesetting and welding battery strings according to claim 7, which is characterized in that the vacuum receiving plate assembly comprises a vacuum receiving plate installed on the vacuum receiving frame, a plurality of receiving grids are uniformly arranged on the vacuum receiving plate, a plurality of vacuum holes are arranged in each receiving grid, and each vacuum hole is connected with a vacuum channel penetrating the vacuum receiving plate, The frame is provided with a vacuum generator, and the vacuum generator communicates with each vacuum channel through a pipeline.

9. The all-in-one machine for typesetting and welding battery strings according to claim 8, which is characterized in that the mobile film sucking base comprises a film sucking linear motor installed on one side of the beam and a film sucking guide rail installed on one side of the beam; The film sucking guide rail is sliding connected with a film sucking support connected with the film sucking linear motor transmission.
the lower two sides of the suction plate support are provided with two suction plate moving supports, each of which is equipped with a suction plate linear motor and a suction plate sliding seat which is connected with the suction plate linear motor drive, and the suction plate sliding seat is sliding installed on the suction plate moving support; A sheet sucking workbench is arranged between the two sheet sucking sliding seats; A vertical suction support is installed on the suction table, a vertical suction cylinder is installed on the top of the vertical suction support, and the vertical suction cylinder is connected with a suction lifting seat through transmission; The lower part of the suction lifting seat is provided with a plurality of suction transverse bars, the lower part of each suction transverse bar is provided with a plurality of suction cup supports, and the suction cup supports are provided with a plurality of suction cups; The sheet suction vacuum generator is installed on the sheet suction workbench, and the sheet suction vacuum generator communicates with each sheet suction cup through a pipeline.

10. The all-in-one machine for typesetting and welding battery strings according to claim 9, which is characterized in that the electromagnetic welding component comprises a welding linear motor installed on the welding base, and the welding linear motor is connected with a welding lifting workbench through transmission; A junction box and a plurality of electromagnetic welding driving plates are installed on the welding lifting workbench, and the lower part of the welding lifting workbench is provided with a plurality of electromagnetic welding joints; The junction box is connected with an external controller, and the junction box is electrically connected with all the electromagnetic welding driving plates; The electromagnetic welding driving plate is electrically connected with the electromagnetic welding joint.
